(19) United States
(12) Patent Application Publication
(10) Pub. No.: US 2026/0080951 A1
(43) Pub. Date: Mar. 19, 2026

(54) SEMICONDUCTOR MEMORY DEVICE

(71) Applicant: Kioxia Corporation, Tokyo (JP)

(72) Inventors: Tomonori KUROSAWA, Zama Kanagawa (JP); Mitsuhiro ABE, Kawasaki Kanagawa (JP); Takeshi OGAWA, Kawasaki Kanagawa (JP)

(21) Appl. No.: 19/063,199

(22) Filed: Feb. 25, 2025

(30) Foreign Application Priority Data
Sep. 18, 2024 (JP) 2024-160801

(51) Int. Cl. G11C 16/30; G11C 5/14

(52) U.S. Cl. CPC G11C 16/30; G11C 5/144; G11C 5/146

(57) ABSTRACT

According to one embodiment, a semiconductor memory device includes an input and output pad group, a memory cell array including a plurality of memory cells, and an input and output circuit provided between the input and output pad group and the memory cell array. The input and output circuit includes a plurality of transistors, and a substrate bias voltage supply circuit that is controllable to supply one of a first voltage having the same value as a power supply voltage of the input and output circuit and a second voltage having a value different from the first voltage as a substrate bias voltage to the plurality of transistors.

### CROSS-REFERENCE TO RELATED APPLICATIONS

This application is based upon and claims the benefit of priority from Japanese Patent Application No. 2024-160801, filed September 18, 2024, the entire contents of which are incorporated herein by reference.

### FIELD

Embodiments described herein relate generally to a semiconductor memory device.

### BACKGROUND

A semiconductor memory device applicable to a nonvolatile memory is known.

### BRIEF DESCRIPTION OF THE DRAWINGS

FIG. 1 is a block diagram illustrating a configuration of a memory system including a semiconductor memory device according to a first embodiment.

FIG. 2 is a block diagram illustrating a configuration of the semiconductor memory device according to the first embodiment.

FIG. 3A is an example of a command sequence for instructing the semiconductor memory device to perform a write operation.

FIG. 3B is an example of a command sequence related to the command sequence for instructing the write operation.

FIG. 4A is an example of a command sequence for instructing the semiconductor memory device to perform a read operation.

FIG. 4B is an example of a command sequence related to the command sequence for instructing the read operation.

FIG. 5 is a block diagram illustrating a part of the configuration of the semiconductor memory device according to the first embodiment.

FIG. 6 is a circuit diagram illustrating an example of a data transmission path applied to an input and output circuit of the semiconductor memory device according to the first embodiment.

FIG. 7 is a diagram illustrating a first operation in the first embodiment.

FIG. 8 is a diagram illustrating a second operation in the first embodiment.

FIG. 9 is a circuit diagram illustrating an example of a data transmission path applied to an input and output circuit of a semiconductor memory device according to a second embodiment.

FIG. 10 is a diagram illustrating a first operation in the second embodiment.

FIG. 11 is a diagram illustrating a second operation in the second embodiment.

### DETAILED DESCRIPTION

Embodiments provide a semiconductor memory device capable of reducing power consumption.

In general, according to one embodiment, a semiconductor memory device includes an input and output pad, a memory cell array including a plurality of memory cells, and an input and output circuit provided between the input and output pad and the memory cell array. The input and output circuit includes a plurality of transistors and a substrate bias voltage supply circuit that is controllable to supply one of a first voltage having the same value as a power supply voltage of the input and output circuit and a second voltage having a value different from the first voltage as a substrate bias voltage to the plurality of transistors.

Embodiments will be described with reference to the drawings. In the description of the drawings described below, the same or similar parts are denoted by the same or similar reference numerals. The drawings are schematic. In addition, the embodiments described below are examples of devices and methods for embodying technical ideas, and are not intended to limit the materials, shapes, structures, arrangements, and the like of parts that can be employed. Various modifications may be made to the embodiments.

### First Embodiment

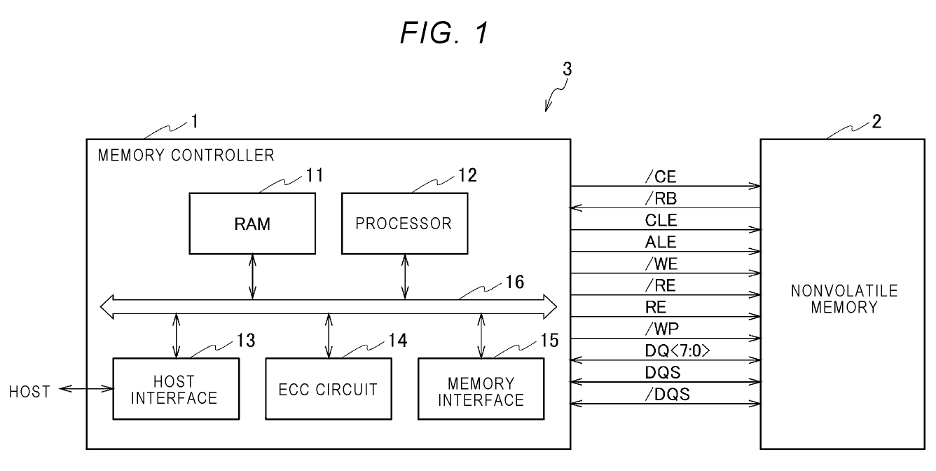

A semiconductor memory device according to a first embodiment may be applied to, for example, a nonvolatile memory 2 included in a memory system 3 illustrated in FIG. 1. The nonvolatile memory 2 is a semiconductor memory that stores data in a nonvolatile manner. The nonvolatile memory 2 includes, for example, a NAND flash memory. The memory controller 1 controls an operation of the nonvolatile memory 2. The host is, for example, an electronic device such as a personal computer or a mobile terminal.

First, the memory system 3 illustrated in FIG. 1 will be described. In the following description, a signal DQ<7:0> means a set of signals DQ<0>, DQ<1>, …, DQ<7>, each of which is a 1-bit signal. The signal DQ<7:0> is an 8-bit signal.

The memory controller 1 receives an instruction from the host and controls the nonvolatile memory 2 based on the received instruction. Specifically, the memory controller 1 writes data instructed to be written by the host to the nonvolatile memory 2, and reads data instructed to be read by the host from the nonvolatile memory 2 and transmits the read data to the host. The memory controller 1 designates a read or write target nonvolatile memory cell of the nonvolatile memory 2. In the following, the nonvolatile memory cell of the nonvolatile memory 2 is also referred to as a "memory cell".

The memory controller 1 and the nonvolatile memory 2 transmit and receive signals conforming to interface standards of the memory controller 1 and the nonvolatile memory 2 via individual signal lines. Signals transmitted and received between the memory controller 1 and the nonvolatile memory 2 include signals /CE, /RB, CLE, ALE, /WE, /RE, RE, /WP, DQ<7:0>, DQS, and /DQS.

The signal /CE is a chip enable signal for enabling the nonvolatile memory 2. The signal /RB is a ready/busy signal which indicates whether the nonvolatile memory 2 is in a ready state (a state in which the nonvolatile memory 2 can receive instructions from the outside) or a busy state (a state in which the nonvolatile memory 2 cannot receive instructions from the outside). The signal CLE is a command latch enable signal that notifies the nonvolatile memory 2 that the signal DQ<7:0> transmitted to the nonvolatile memory 2 while the signal CLE is at a High (H) level is a command. The signal ALE is an address latch enable signal that notifies the nonvolatile memory 2 that the signal DQ<7:0> transmitted to the nonvolatile memory 2 while the signal ALE is at H level is an address. The signal /WE is a write enable signal that instructs the nonvolatile memory 2 to take in the signal DQ<7:0> transmitted to the nonvolatile memory 2. In a single data rate (SDR) mode, the signal /WE instructs the nonvolatile memory 2 to take in the signal DQ<7:0> as a command, address, or data transmitted to the nonvolatile memory 2 at a rising edge thereof. In a double data rate (DDR) mode, the signal /WE instructs the nonvolatile memory 2 to take in the signal DQ<7:0> as a command or address at a rising edge thereof. The signal /WE is asserted each time the nonvolatile memory 2 receives a command, an address, and data from the memory controller 1.

The signal /RE is a read enable signal that instructs the memory controller 1 to read the signal DQ<7:0> from the nonvolatile memory 2. The signal RE is a complementary signal of the signal /RE. For example, the signals /RE and RE are used to control the timing at which the nonvolatile memory 2 outputs the signal DQ<7:0>. More specifically, in the single data rate mode, the signal /RE instructs the nonvolatile memory 2 to output the signal DQ<7:0> as data at a falling edge thereof. In the double data rate mode, the signal /RE instructs the nonvolatile memory 2 to output the signal DQ<7:0> as data at the falling edge and rising edge thereof. The signal /WP is a write protect signal that instructs the nonvolatile memory 2 to prohibit writing of data.

The signal DQ<7:0> contains data transmitted and received between the nonvolatile memory 2 and the memory controller 1. The signal DQ<7:0> includes a command CMD, an address ADD, and data DAT. The data DAT includes data to be written to the nonvolatile memory (hereinafter also referred to as "write data") and data read from the nonvolatile memory (hereinafter also referred to as "read data"). The signal DQS is a data strobe signal used to control the operation timing of the nonvolatile memory 2 related to the signal DQ<7:0>. The signal /DQS is a complementary signal of the signal DQS. The signals DQS and /DQS are generated based on, for example, the signals RE and /RE. More specifically, in the double data rate mode, the signal DQS instructs the nonvolatile memory 2 to take in the signal DQ<7:0> as data at the falling edge and rising edge thereof. In the double data rate mode, the signal DQS is generated based on the falling edge and rising edge of the signal /RE, and is output from the nonvolatile memory 2 together with the signal DQ<7:0> as data.

The memory controller 1 includes a RAM 11, a processor 12, a host interface 13, an ECC circuit 14, and a memory interface 15. The RAM 11, the processor 12, the host interface 13, the ECC circuit 14, and the memory interface 15 are connected to one another by a bus 16.

The RAM 11 temporarily stores data received from the host until the received data is stored in the nonvolatile memory 2, and temporarily stores data read from the nonvolatile memory 2 until the read data is transmitted to the host. The RAM 11 is, for example, a general-purpose semiconductor memory such as a static random access memory (SRAM) or a dynamic random access memory (DRAM).

The processor 12 controls an operation of the entire memory controller 1. The processor 12 is, for example, a central processing unit (CPU), a micro processing unit (MPU), or the like. The processor 12 issues, for example, a read instruction to the nonvolatile memory 2 in response to a read instruction of data received from the host. This operation is similar to the case of data writing. The processor 12 determines a storage area (memory area) of the nonvolatile memory 2 for data stored in the RAM 11. The processor 12 has a function of executing various operations on data read from the nonvolatile memory 2.

The host interface 13 is connected to the host and executes processing according to an interface standard with the host. The host interface 13 transfers instructions and data received from the host to the processor 12, for example. The host interface 13 also transmits data read from the nonvolatile memory 2, responses from the processor 12, and the like to the host.

The ECC circuit 14 encodes the data stored in the RAM 11 to generate a code word. In addition, the ECC circuit 14 decodes the code word read from the nonvolatile memory 2.

The memory interface 15 is connected to the nonvolatile memory 2 via a bus and performs communication with the nonvolatile memory 2. The memory interface 15 transmits a command CMD, an address ADD, and write data to the nonvolatile memory 2 in response to an instruction from the processor 12. The memory interface 15 receives read data from the nonvolatile memory 2.

FIG. 1 illustrates an example of a configuration in which the memory controller 1 includes the ECC circuit 14 and the memory interface 15 as separate components. However, the ECC circuit 14 may be built into the memory interface 15. The ECC circuit 14 may also be built into the nonvolatile memory 2.

When a write instruction is received from the host, the memory system 3 operates as follows. The processor 12 temporarily stores the data instructed to be written in the RAM 11. The processor 12 reads the data stored in the RAM 11 and inputs the read data to the ECC circuit 14. The ECC circuit 14 encodes the input data and inputs the codeword to the memory interface 15. The memory interface 15 writes the input codeword to the nonvolatile memory 2.

When a read command is received from the host, the memory system 3 operates as follows. The memory interface 15 inputs the codeword read from the nonvolatile memory 2 to the ECC circuit 14. The ECC circuit 14 decodes the input codeword and stores the decoded data in the RAM 11. The processor 12 transmits the data stored in the RAM 11 to the host via the host interface 13.

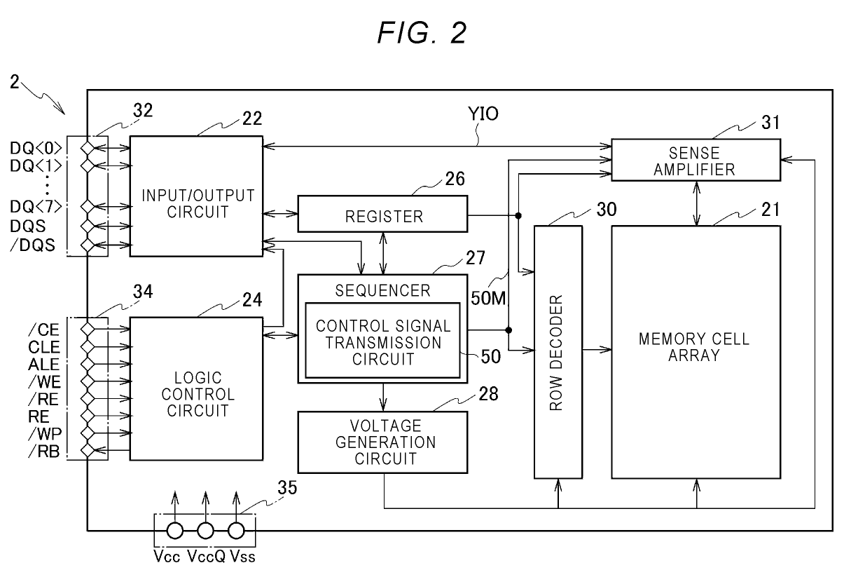

FIG. 2 is a block diagram illustrating an example of the configuration of the nonvolatile memory 2. The nonvolatile memory 2 includes a memory cell array 21, an input and output circuit 22, a logic control circuit 24, a register 26, a sequencer 27, a voltage generation circuit 28, a row decoder 30, a sense amplifier 31, and a control signal transmission circuit 50. Furthermore, the nonvolatile memory 2 includes an input and output pad group 32, a logic control pad group 34, and a power supply input terminal group 35.

The memory cell array 21 includes a plurality of memory cells (not illustrated) associated with word lines and bit lines. The memory cell array 21 includes, for example, a NAND string.

The input and output circuit 22 transmits and receives signals DQ<7:0>, DQS, and /DQS to and from the memory controller 1. The input and output circuit 22 transfers the command CMD and address ADD in the signal DQ<7:0> to the register 26. The input and output circuit 22 also transmits and receives write data and read data to and from the sense amplifier 31.

The logic control circuit 24 receives signals /CE, CLE, ALE, /WE, /RE, RE, /WP, and /RB from the memory controller 1. The logic control circuit 24 also transfers a signal /RB to the memory controller 1 to notify a state of the nonvolatile memory 2 to the outside.

The register 26 stores the command CMD and the address ADD. The register 26 transfers the address ADD to the row decoder 30 and the sense amplifier 31, and also transfers the command CMD to the sequencer 27.

The sequencer 27 receives the command CMD and controls the entire nonvolatile memory 2 according to a sequence based on the received command CMD. The sequencer 27 supplies a control signal to the row decoder 30 and the sense amplifier 31, for example, via a control signal wiring 50M. For example, a plurality of control signal wirings 50M may be provided. In this case, a plurality of types of control signals are supplied from the sequencer 27 to the row decoder 30 and/or the sense amplifier 31 via the plurality of control signal wirings 50M, respectively.

The voltage generation circuit 28 generates voltages required for operations such as writing data, reading data, and erasing data based on instructions from the sequencer 27. Based on the address from the register 26, various voltages are supplied from the voltage generation circuit 28 to the row decoder 30, the sense amplifier 31, and the memory cell array 21.

The row decoder 30 receives a block address and row address in the address ADD from the register 26. The row decoder 30 selects a block based on the block address and selects a word line based on the row address.

The sense amplifier 31 is connected to the memory cell array 21. During reading of data, the sense amplifier 31 senses read data read from the memory cell using the bit line and transfers the sensed read data to the input and output circuit 22. During writing of data, the sense amplifier 31 stores write data in the memory cell using the bit line.

Data transfer between the input and output circuit 22 and the sense amplifier 31 is performed via a data bus YIO. The data bus YIO includes a plurality of data wirings connected between the input and output circuit 22 and the sense amplifier 31. Data to be written to the nonvolatile memory 2 and data read from the nonvolatile memory 2 propagate through the data bus YIO.

The control signal transmission circuit 50 generates a clock signal used for the operation of the nonvolatile memory 2 based on the signals /RE and RE supplied from the memory controller 1. In FIG. 2, the control signal transmission circuit 50 is illustrated as a part of the sequencer 27. However, the control signal transmission circuit 50 may be configured as a part of the input and output circuit 22 and/or the logic control circuit 24, for example. The control signal transmission circuit 50 may also be configured as a circuit different from any of the sequencer 27, the input and output circuit 22, and the logic control circuit 24.

The input and output pad group 32 includes a plurality of terminals (pads) corresponding to the signals DQ<7:0> and the signals DQS and /DQS. These terminals are used to transmit and receive each such signal including data between the nonvolatile memory 2 and the memory controller 1.

The logic control pad group 34 includes a plurality of terminals (pads) corresponding to the signals /CE, CLE, ALE, /WE, /RE, RE, /WP, and /RB. These terminals are used to transmit and receive each such signal between the nonvolatile memory 2 and the memory controller 1.

The power supply input terminal group 35 includes a plurality of terminals to which a first power supply voltage Vcc, a second power supply voltage VccQ, and a ground voltage Vss (which is a third power supply voltage) are input in order to supply various operating power from the outside to the nonvolatile memory 2. The first power supply voltage Vcc is a circuit power supply voltage that is generally applied from the outside as operating power. The first power supply voltage Vcc is a power supply voltage supplied to a core portion of a semiconductor chip (hereinafter simply referred to as a "chip") on which the nonvolatile memory 2 is formed, and is, for example, 2.5 V. The second power supply voltage VccQ is used when transmitting and receiving signals between the memory controller 1 and the nonvolatile memory 2, and is, for example, 1.2 V.

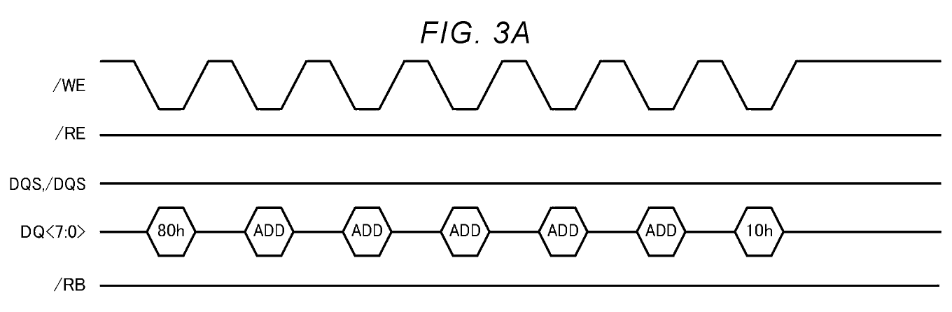

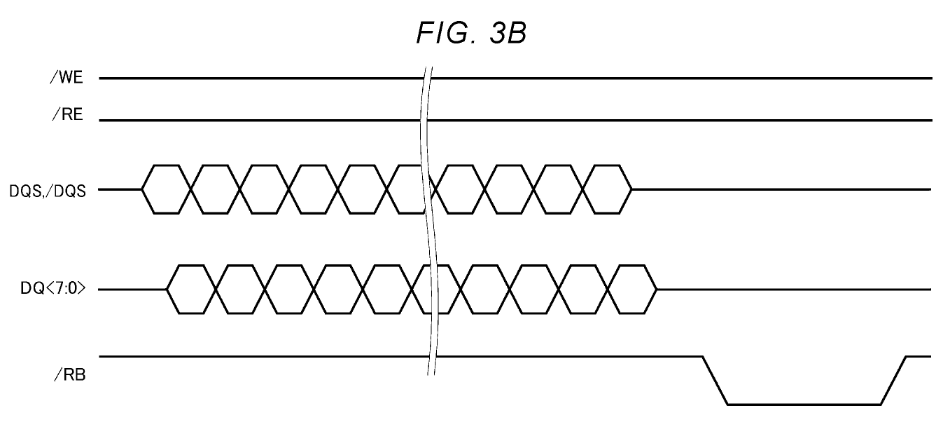

FIG. 3A illustrates an example of a command sequence for instructing the nonvolatile memory to perform a write operation (hereinafter also referred to as a "data in operation"). FIG. 3B illustrates an example of a command sequence related to the data-in operation.

As illustrated in FIG. 3A, in the data in operation, the memory controller 1 issues a command set for instructing the data in operation to the nonvolatile memory 2 while toggling the signal /WE. The command set for instructing the data-in operation includes, for example, a read command "80h", an address ADD over five cycles, and a command "10h". The read command "80h" is a command to instruct writing of data to a user data area in the memory cell array 21. The command "10h" is a command to instruct the start of the data in operation.

After the command "10h", the memory controller 1 transfers data to be written to the memory cell array 21 as a signal DQ<7:0> to the nonvolatile memory 2 as illustrated in FIG. 3B. When transferring data to be written to the nonvolatile memory 2, the memory controller 1 toggles the signals DQS and /DQS in synchronization with the signal DQ<7:0> and transfers the data to the nonvolatile memory 2.

Upon receiving the data to be written, the nonvolatile memory 2 starts a write operation of writing data to a user data area in the memory cell array 21, sets the signal /RB to an L level, and informs the memory controller 1 that the nonvolatile memory 2 is in a busy state. After the write operation is completed, the nonvolatile memory 2 sets the signal /RB to a H level and informs the memory controller 1 that the nonvolatile memory 2 is in a ready state.

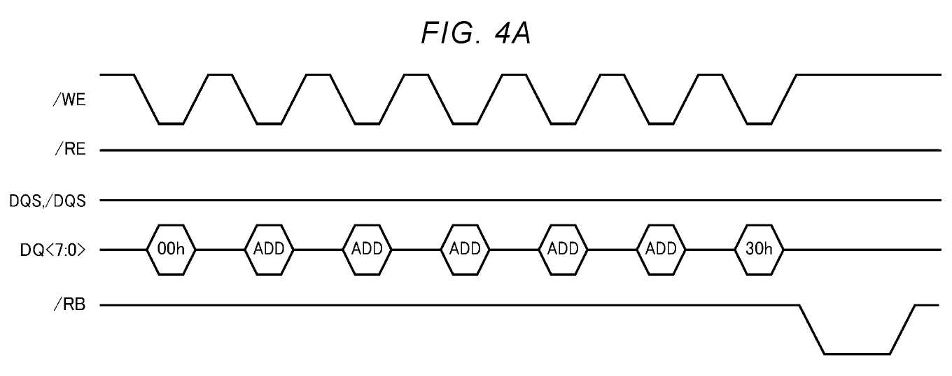

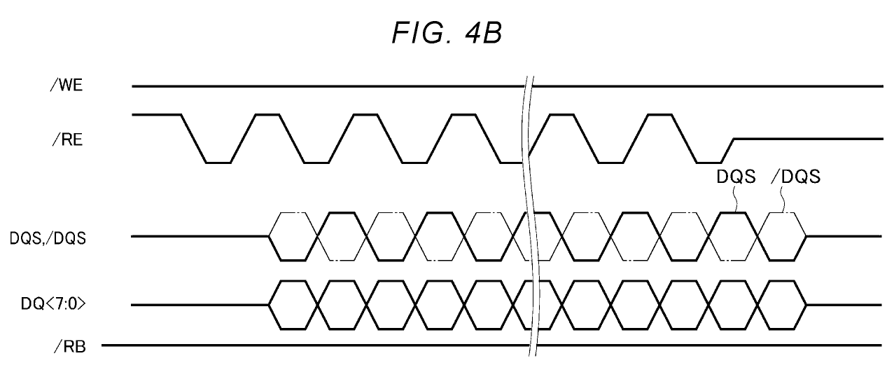

FIG. 4A illustrates an example of a command sequence for instructing the nonvolatile memory 2 to perform a read operation. FIG. 4B illustrates an example of a command sequence related to the data out operation which is performed subsequent to the read operation.

As illustrated in FIG. 4A, in the data out operation, the memory controller 1 issues a command set for instructing the data out operation to the nonvolatile memory 2 while toggling the signal /WE. The command set for instructing the data out operation includes, for example, a read command "00h", an address ADD over five cycles, and a command "30h". The read command "00h" is a command to instruct reading of data from the memory cell array 21 of the nonvolatile memory 2. The command "30h" is a command to instruct the start of the data out operation. Upon receiving the command "30h", the nonvolatile memory 2 starts a read operation of reading data from the memory cell array 21, sets the signal /RB to an L level, and informs the memory controller 1 that the nonvolatile memory 2 is in a busy state. After the read operation is completed, the nonvolatile memory 2 sets the signal /RB to an H level and informs the memory controller 1 that the nonvolatile memory 2 is in a ready state.

After checking that the nonvolatile memory 2 is in the ready state, the memory controller 1 toggles the signals /RE and RE as illustrated in FIG. 4B. The nonvolatile memory 2 transfers the read data to the memory controller 1 as the signal DQ<7:0> in synchronization with the signals /RE and RE. The nonvolatile memory 2 also toggles the signals DQS and /DQS in synchronization with the signal DQ<7:0> and transfers the data to the memory controller 1.

Alternatively, after checking that the nonvolatile memory 2 is in the ready state, the memory controller 1 may issue a command set for instructing the data out operation to the nonvolatile memory 2 while toggling the signal /WE. The command set for instructing the data out operation includes, for example, a data out command "05h", an address ADD over five cycles, and a command "E0h". In this case, the memory controller 1 transmits the command "E0h" to the nonvolatile memory 2, and then toggles the signals /RE and RE after a predetermined period of time elapses. The nonvolatile memory 2 transfers the read data to the memory controller 1 as the signal DQ<7:0> in synchronization with the signals /RE and RE. Furthermore, the nonvolatile memory 2 toggles the signals DQS and /DQS in synchronization with the signal DQ<7:0> and transfers the signals to the memory controller 1.

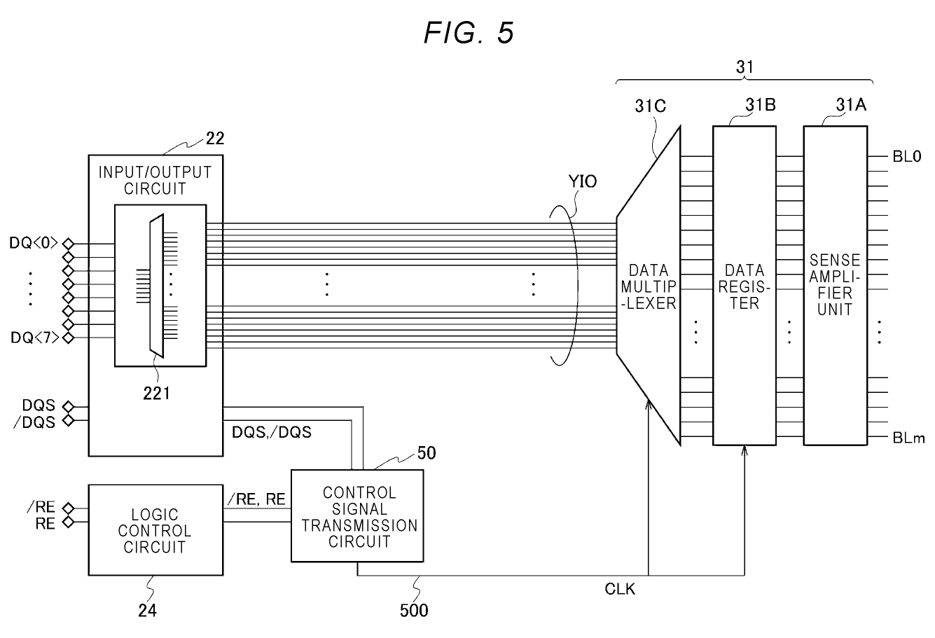

FIG. 5 is a block diagram illustrating a part of the configuration of the nonvolatile memory 2. Hereinafter, with reference to FIG. 5, transmission and reception of data between the input and output circuit 22 and the sense amplifier 31 in the nonvolatile memory 2 will be described.

The input and output circuit 22 transmits and receives write data and read data to and from the sense amplifier 31 via the data bus YIO. The data bus YIO has a configuration in which a plurality of data wirings connected between the input and output circuit 22 and the sense amplifier 31 are disposed adjacent to each other without being shielded. The data bus YIO includes, for example, 200 data wirings. By not shielding the data wirings, the increase in an area of a chip on which the nonvolatile memory 2 is formed can be reduced.

The sense amplifier 31 includes a sense amplifier unit 31A connected to bit lines BL0 to BLm, a data register 31B connected to the sense amplifier unit 31A, and a data multiplexer 31C connected to the data register 31B. The number of bit lines is, for example, approximately 130,000 lines. The sense amplifier unit 31A senses read data using the bit line and transfers write data to the memory cell using the bit line. The data register 31B stores the read data and the write data. The data multiplexer 31C selects data propagating through the signal lines that make up the data bus YIO from data propagating through the bit lines BL0 BLm.

The input and output circuit 22 may include a conversion circuit 221 that converts a bus width. The conversion circuit 221 converts the bus width of the data bus YIO, which includes, for example, 128 bit lines, into a bus including 8 signal lines through which the signals DQ<7:0> respectively propagate. The conversion circuit 221 may be, for example, a First In First Out (FIFO) circuit. For example, the operations between the sense amplifier 31 and the input and output circuit 22 and between the input and output circuit 22 and the memory controller 1 are performed at the second power supply voltage VccQ (e.g., 1.2 V).

The control signal transmission circuit 50 is, for example, a part of the sequencer 27 illustrated in FIG. 2. The control signal transmission circuit 50 generates a clock signal CLK based on the signals /RE and RE supplied from the memory controller 1 in the data out operation, for example.

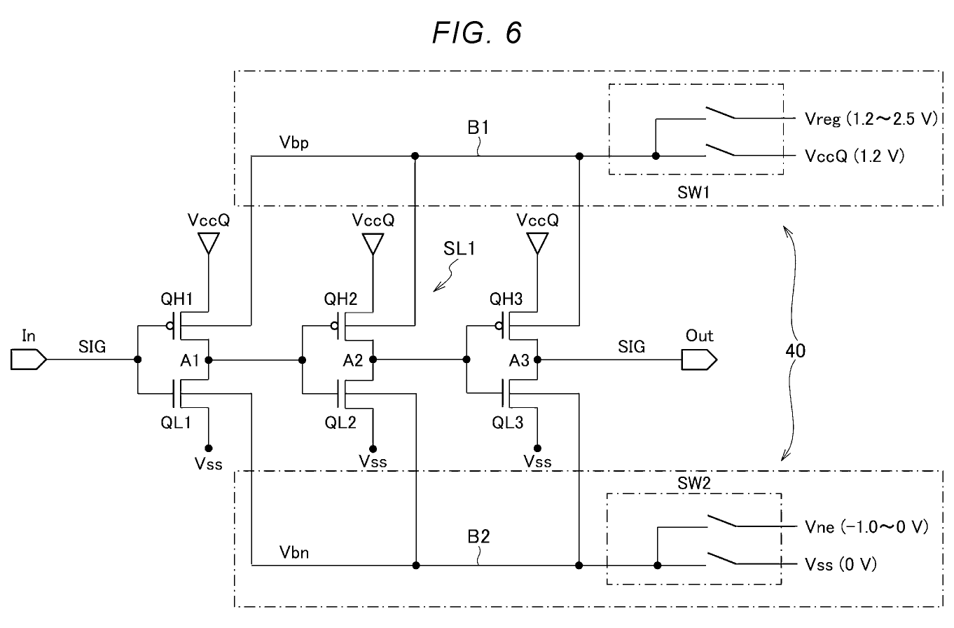

FIG. 6 is a circuit diagram illustrating an example of a data transmission path SL1 and a substrate bias voltage supply circuit 40 applied to the input and output circuit 22 in the first embodiment. The data transmission path SL1 is for transmitting data SIG from a data input terminal In to a data output terminal Out. The data SIG is, for example, a binary digital signal having levels of the second power supply voltage VccQ and a ground voltage Vss.

The input and output circuit 22 includes a plurality of data transmission paths SL1 configured with a plurality of arms A1 to A3 provided between the data input terminal In and the data output terminal Out, and the substrate bias voltage supply circuit 40. The data input terminal In is connected to, for example, one of the signal lines that form the data bus YIO. The data output terminal Out is connected to, for example, a corresponding terminal (pad) of the input and output pad group 32 via the conversion circuit 221.

In FIG. 6, three arms A1 to A3 are represented for simplification, but any number of arms may be disposed according to a length of the data transmission path SL1. Any number of data transmission paths SL1 according to the number of signal lines that form the data bus YIO may be provided inside the input and output circuit 22.

In the data transmission path SL1, each of the arms A1 to A3 has the same configuration, and thus the configuration thereof will be described using the first arm A1, and the configurations of the second arm A2 and the third arm A3 will be omitted. The first arm A1 includes a high-side transistor QH1 and a low-side transistor QL1. The high-side transistor QH1 is configured with a P-channel MOSFET. The low-side transistor QL1 is configured with an N-channel MOSFET.

A first electrode (drain) of the high-side transistor QH1 is connected to the second power supply voltage VccQ. A second electrode (source) of the high-side transistor QH1 is connected to a first electrode (drain) of the low-side transistor QL1. A second electrode (source) of the low-side transistor QL1 is connected to the ground voltage Vss. In other words, the high-side transistor QH1 and the low-side transistor QL1 form a CMOS circuit. A control electrode (gate) of the high-side transistor QH1 and a control electrode (gate) of the low-side transistor QL1 are connected to the data input terminal In. A connection point between the high-side transistor QH1 and the low-side transistor QL1 is connected to the control electrode (gate) of the high-side transistor QH2 and the control electrode (gate) of the low-side transistor QL2 of the second arm A2 adjacent to the downstream of the first arm A1. A connection point between the high-side transistor QH3 and the low-side transistor QL3 of the third arm A3 located at the most downstream side is connected to the data output terminal Out.

A back gate (substrate electrode) of the high-side transistor QH1 is connected to a first switch SW1 via a first bias wiring B1. The first switch SW1 is configured for switching between the second power supply voltage VccQ (e.g., 1.2 V) and a regulating voltage Vreg (e.g., which is in the range of 1.2 to 2.5 V) for connection with the first bias wiring B1.

The regulating voltage Vreg may be variably set within a range of, for example, 1.2 to 2.5 V, or may be a fixed value within a range of 1.2 to 2.5 V that is greater than the second power supply voltage VccQ. The regulating voltage Vreg may be, for example, a power supply voltage used in parts other than the input and output circuit 22 of the chip on which the nonvolatile memory 2 is formed, or may be a power supply voltage supplied to the input and output circuit 22. The regulating voltage Vreg may be a voltage regulated from the first power supply voltage Vcc. The regulating voltage Vreg may also be a dedicated power supply voltage supplied from outside the chip on which the nonvolatile memory 2 is formed. The first switch SW1 may be configured for switching between a plurality of regulating voltages Vreg for connection with the first bias wiring B1. With this configuration, a configuration in which a value of a first substrate bias voltage Vbp supplied to the back gate (substrate electrode) of the high-side transistor QH1 is made variable is realized.

The back gate (substrate electrode) of the low-side transistor QL1 is connected to a second switch SW2 via a second bias wiring B2. The second switch SW2 is configured for switching between a ground voltage Vss (e.g., 0 V) and a negative power supply voltage Vne (e.g., which is in the range of -1.0 to 0 V) for connection with the second bias wiring B2.

The negative power supply voltage Vne may be used as is or regulated if there is a negative power supply voltage to be used in a part other than the input and output circuit 22 of the chip on which the nonvolatile memory 2 is formed, or a dedicated power supply voltage may be supplied from outside the chip on which the nonvolatile memory 2 is formed. The second switch SW2 may be configured for switching between a plurality of negative power supply voltages Vne for connection with the second bias wiring B2. With this configuration, a configuration in which the value of the second substrate bias voltage Vbn supplied to the back gate (substrate electrode) of the low-side transistor QL1 is made variable is realized.

The first bias wiring B1, the first switch SW1, the second bias wiring B2, and the second switch SW2 make up the substrate bias voltage supply circuit 40. A plurality of data transmission paths SL1 are provided inside the input and output circuit 22. The substrate bias voltage supply circuit 40 is configured so that one substrate bias voltage supply circuit 40 is shared by the plurality of data transmission paths SL1 provided inside the input and output circuit 22. The plurality of data transmission paths SL1 may also be classified into a plurality of data transmission path groups, and one substrate bias voltage supply circuit 40 may be shared by each data transmission path group.

During the first operation, which is a normal operation that does not require reduction of power consumption, the second power supply voltage VccQ is supplied as the first substrate bias voltage Vbp, and the ground voltage Vss is supplied as the second substrate bias voltage Vbn. During the first operation, operating threshold voltages of the control electrodes of the high-side transistor QH1 and the low-side transistor QL1 are set to target values, so that the data transmission path SL1 and the nonvolatile memory 2 can be operated at a relatively high speed (e.g., for 4.8 Gbps applications).

In contrast, during the second operation, which requires reduction of power consumption, the regulating voltage Vreg is supplied as the first substrate bias voltage Vbp, and the negative power supply voltage Vne is supplied as the second substrate bias voltage Vbn. During the second operation, the operating threshold voltages of the control electrodes of the high-side transistor QH1 and the low-side transistor QL1 are set to values higher than the target values due to the substrate bias effect, so that the current consumption can be reduced. Therefore, in the second operation, the data transmission path SL1 and the nonvolatile memory 2 are operated at a relatively low speed (e.g., for 1.4 Gbps), but power consumption can be reduced more than in the first operation. The user can switch between the first operation and the second operation depending on the application.

According to the inventors' research, the following has been confirmed by circuit simulation. For example, by switching the first substrate bias voltage Vbp of the high-side transistor QH1, which is configured with a P-channel MOSFET, from 1.2 V (first operation) to 1.65 V (second operation), the operating threshold voltage of the control electrode could be shifted to a high potential side by 53 mV. With this configuration, a reduction in current consumption of approximately 16 mA can be expected by a single high-side transistor QH1. This means that when considering the input and output circuit 22 as a whole, the power consumption can be reduced considerably.

By further increasing the insulation of the high-side transistor QH1 against the first substrate bias voltage Vbp and enabling the application of a larger first substrate bias voltage Vbp, power consumption can be further reduced.

When the data bus YIO is driven at the second power supply voltage VccQ, the data transmission path SL1 and the substrate bias voltage supply circuit 40 can be applied to the portion of the data bus YIO as well. With this configuration, when the input and output circuit 22 is considered as a whole, power consumption can be further reduced. In the above description, although the data transmission path SL1 is described above as an example, the substrate bias voltage supply circuit 40 may regulate the operating threshold voltages of transistors in other circuits provided in the input and output circuit 22.

In this way, according to the first embodiment, a semiconductor memory device capable of reducing power consumption can be provided.

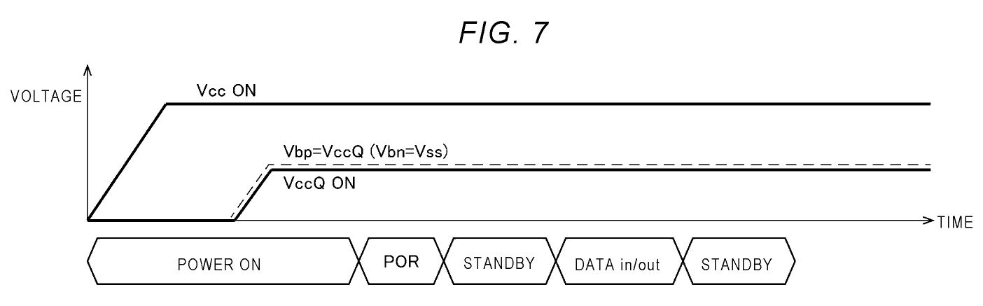

Next, the first operation, which is a normal operation, is described with reference to FIG. 7. When the nonvolatile memory 2 is powered on by an instruction from the host or the memory controller 1, the first power supply voltage Vcc is turned on, and then the second power supply voltage VccQ is turned on. Then, the second power supply voltage VccQ is applied as the first substrate bias voltage Vbp, and the ground voltage Vss is applied as the second substrate bias voltage Vbn.

Next, in response to a start-up instruction (POR: Power-On-Read) from the memory controller 1, the nonvolatile memory 2 reads operating parameters from a part of the memory cell array 21 and sets the operating parameters to, for example, a register provided in the sequencer 27, and after a start-up sequence, the nonvolatile memory 2 goes into a waiting state (standby). Next, in response to an instruction from the memory controller 1, the nonvolatile memory 2 can repeat writing and reading data at high speed (e.g., for 4.8 Gbps applications) and the waiting state.

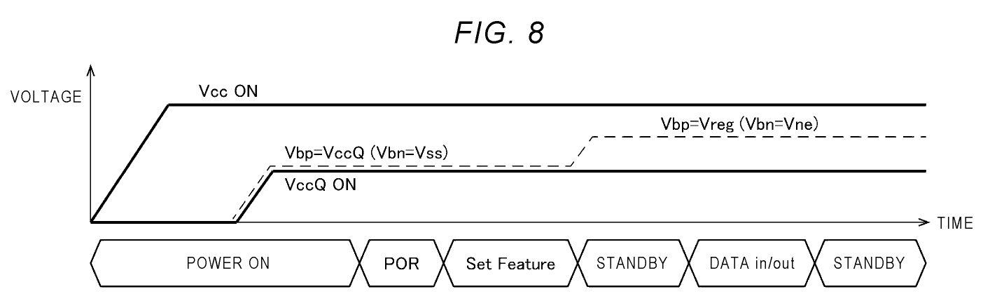

Next, the second operation which requires reduction of power consumption is described with reference to FIG. 8. When the nonvolatile memory 2 is powered on by an instruction from the host or the memory controller 1, the first power supply voltage Vcc is turned on, and then the second power supply voltage VccQ is turned on. Then, the second power supply voltage VccQ is applied as the first substrate bias voltage Vbp, and the ground voltage Vss is applied as the second substrate bias voltage Vbn.

Next, in response to a start-up instruction (POR: Power-On-Read) from the memory controller 1, the nonvolatile memory 2 reads operating parameters from the part of the memory cell array 21 and sets the operating parameters to the register in the sequencer 27, and the nonvolatile memory 2 goes into the waiting state. Next, in response to a "Set Feature" command from the memory controller 1, the first switch SW1 and the second switch SW2 are switched, and the regulating voltage Vreg is applied as the first substrate bias voltage Vbp, and the negative power supply voltage Vne is applied as the second substrate bias voltage Vbn. In this case, both the first switch SW1 and the second switch SW2 can be set by the "Set Feature" command so as to be switched, or either the first switch SW1 or the second switch SW2 can be set by the "Set Feature" command so as to be switched.

Next, the nonvolatile memory 2 goes into a waiting state (standby). Next, in response to an instruction from the memory controller 1, the nonvolatile memory 2 can repeat writing and reading of data at a low speed (e.g., for 1.4 Gbps applications) and with low power consumption and the waiting state.

### Second Embodiment

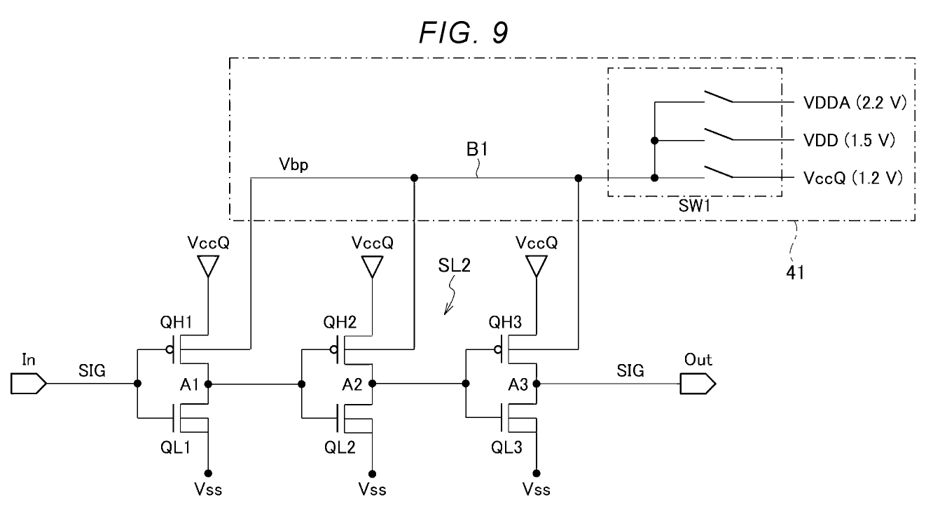

A data transmission path SL2 and a substrate bias voltage supply circuit 41 according to a second embodiment will be described with reference to FIG. 9. The second embodiment differs from the first embodiment in the following points. In a first arm A1 of a data transmission path SL2, a back gate (substrate electrode) of a high-side transistor QH1 is connected to a first switch SW1 via a first bias wiring B1. The first switch SW1 is configured for switching between a second power supply voltage VccQ (e.g., 1.2 V), a fourth power supply voltage VDD (e.g., 1.5 V), and a fifth power supply voltage VDDA (e.g., 2.2 V) for connection with the first bias wiring B1. In the second embodiment, the first bias wiring B1 and the first switch SW1 make up the substrate bias voltage supply circuit 41. The number of power supply voltages between which the first switch SW1 can switch is not limited to three, and the first switch SW1 can be configured to switch between any number of power supply voltages.

Here, the fourth power supply voltage VDD and the fifth power supply voltage VDDA are, for example, power supply voltages supplied to a portion of the chip on which the nonvolatile memory 2 is formed, which is different from the input and output circuit 22. With this configuration, a configuration in which a value of the first substrate bias voltage Vbp supplied to the back gate (substrate electrode) of the high-side transistor QH1 is made variable depending on the values of the plurality of power supply voltages supplied to the nonvolatile memory 2 is realized.

The back gate (substrate electrode) of a low-side transistor QL1 is connected to a ground voltage Vss. A second arm A2 and a third arm A3 are configured similarly to the first arm A1, and therefore description thereof is omitted. Other configurations of the second embodiment are the same as those of the first embodiment, and thus description thereof will not be described.

In the second embodiment, a configuration in which the first substrate bias voltage Vbp of the high-side transistor QH1, which is configured with a P-channel MOSFET requiring a positive substrate bias voltage, is made variable and the second substrate bias voltage Vbn is fixed, is adopted. The second substrate bias voltage Vbn of the low-side transistor QL1, which is configured with an N-channel MOSFET requiring a negative substrate bias voltage, is fixed to the ground voltage Vss. Furthermore, a configuration in which the value of the first substrate bias voltage Vbp is made variable depending on the values of a plurality of power supply voltages supplied to the nonvolatile memory 2 from the outside is adopted. Therefore, in the second embodiment, a simpler circuit configuration can be achieved compared to the first embodiment.

In the second embodiment, similarly to the first embodiment, a semiconductor memory device that can reduce power consumption can be provided.

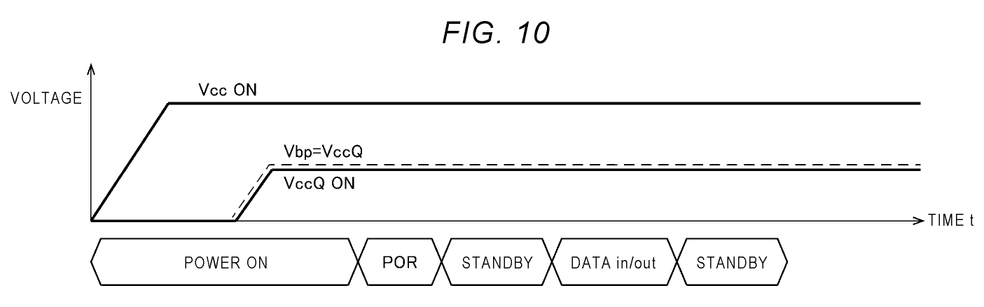

Next, the first operation, which is a normal operation, is described with reference to FIG. 10. When the nonvolatile memory 2 is powered on by an instruction from the host or the memory controller 1, the first power supply voltage Vcc is turned on, and then the second power supply voltage VccQ is turned on. Then, the second power supply voltage VccQ is applied as the first substrate bias voltage Vbp.

Next, in response to a start-up instruction (POR: Power-On-Read) from the memory controller 1, the nonvolatile memory 2 reads operating parameters from the part of the memory cell array 21 and sets the operating parameters to the register in the sequencer 27, and after the start-up sequence, the nonvolatile memory 2 goes into a waiting state (standby). Next, in response to an instruction from the memory controller 1, the nonvolatile memory 2 can repeat writing and reading of data at high speed (e.g., for 4.8 Gbps applications) and the waiting state.

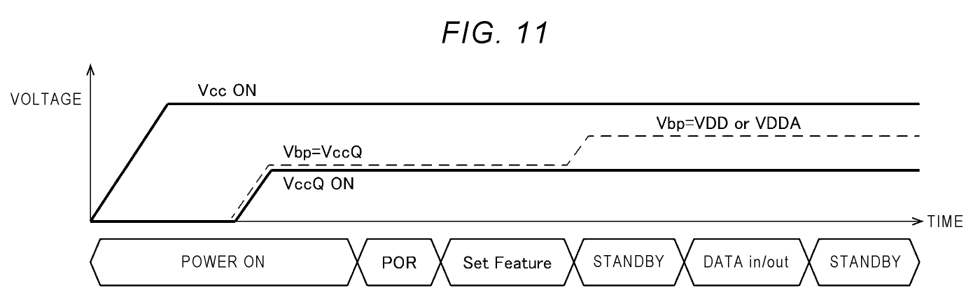

Next, the second operation that requires reduction of power consumption is described with reference to FIG. 11. When the nonvolatile memory 2 is powered on by an instruction from the host or the memory controller 1, the first power supply voltage Vcc is turned on, and then the second power supply voltage VccQ is turned on. Then, the second power supply voltage VccQ is applied as the first substrate bias voltage Vbp.

Next, in response to a start-up instruction (POR: Power-On-Read) from the memory controller 1, the nonvolatile memory 2 reads operating parameters from the part of the memory cell array 21 and sets the operating parameters to the register in the sequencer 27, and the nonvolatile memory goes into the waiting state. Next, in response to a "Set Feature" command from the memory controller 1, the first switch SW1 is switched, and a fourth power supply voltage VDD or a fifth power supply voltage VDDA is applied as the first substrate bias voltage Vbp according to a user's selection. Next, the nonvolatile memory 2 goes into a waiting state (standby). Next, in response to an instruction from the memory controller 1, the nonvolatile memory 2 can repeat writing and reading of data at low speed (e.g., for 1.4 Gbps applications) and with low power consumption, and goes into a waiting state.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
an input and output pad;
a memory cell array including a plurality of memory cells; and
an input and output circuit provided between the input and output pad and the memory cell array, and including:
a plurality of transistors; and
a substrate bias voltage supply circuit that is controllable to supply one of a first voltage having the same value as a power supply voltage of the input and output circuit and a second voltage having a value different from the first voltage as a substrate bias voltage to the plurality of transistors.

2. The semiconductor memory device according to claim 1, wherein
the plurality of transistors include a P-channel MOSFET,
the first voltage supplied as the substrate bias voltage of the P-channel MOSFET is a positive voltage, and
the second voltage supplied as the substrate bias voltage of the P-channel MOSFET is a positive voltage greater than the first voltage.

3. The semiconductor memory device according to claim 2, wherein
the second voltage has the same value as a power supply voltage of a portion of the semiconductor memory device that is different from the input and output circuit.

4. The semiconductor memory device according to claim 1, wherein
the plurality of transistors include an N-channel MOSFET,
the first voltage supplied as the substrate bias voltage of the N-channel MOSFET is a ground voltage, and
the second voltage supplied as the substrate bias voltage of the N-channel MOSFET is a negative voltage.

5. The semiconductor memory device according to claim 1, wherein
the plurality of transistors include a P-channel MOSFET and an N-channel MOSFET,
the first voltage supplied as the substrate bias voltage of the P-channel MOSFET is a positive voltage, and
the second voltage supplied as the substrate bias voltage of the P-channel MOSFET is a positive voltage greater than the first voltage.

6. The semiconductor memory device according to claim 5, wherein
the P-channel MOSFET and the N-channel MOSFET form a CMOS circuit in which a source of the P-channel MOSFET and a drain of the N-channel MOSFET are connected to each other.

7. The semiconductor memory device according to claim 1, further comprising:
a substrate bias voltage supply line through which the substrate bias voltage supply circuit supplies the substrate bias voltage to the plurality of transistors, wherein
the substrate bias voltage supply circuit further includes a switch that connects a first power supply line that is at the first voltage to the substrate bias voltage supply line or a second power supply line that is at the second voltage to the substrate bias voltage supply line.

8. The semiconductor memory device according to claim 7, wherein a position of the switch is set in response to a set feature command.

9. A semiconductor memory device comprising:
an input and output pad;
a memory cell array including a plurality of memory cells; and
an input and output circuit provided between the input and output pad and the memory cell array, and including:
a plurality of CMOS circuits connected in series, each including a P-channel MOSFET and an N-channel MOSFET, wherein a source of the P-channel MOSFET and a drain of the N-channel MOSFET are connected to each other;
a first substrate bias voltage supply line through which a first substrate bias voltage is supplied to the P-channel MOSFETs;
a second substrate bias voltage supply line through which a second substrate bias voltage is supplied to the N-channel MOSFETs;
a first switch that connects either a first power supply line that is at a first voltage or a second power supply line that is at a second voltage that is greater than the first voltage, to the first substrate bias voltage supply line; and
a second switch that connects either a third power supply line that is at a third voltage or a fourth power supply line that is at a fourth voltage that is less than the third voltage, to the second substrate bias voltage supply line.

10. The semiconductor memory device according to claim 9, wherein the first voltage is used when transmitting and receiving signals through the input and output pad, and the third voltage is ground voltage.

11. The semiconductor memory device according to claim 9, wherein the first voltage is 1.2 V and the third voltage is 0 V.

12. The semiconductor memory device according to claim 11, wherein the second voltage is between 1.2 V and 2.5 V and the fourth voltage is between -1.0 V and 0 V.

13. The semiconductor memory device according to claim 9, wherein a position of the first switch and a position of the second switch are set in response to a set feature command.

14. A method of selecting a data transmission rate in a semiconductor memory device comprising an input and output pad, a memory cell array including a plurality of memory cells, and an input and output circuit provided between the input and output pad and the memory cell array, wherein
the input and output circuit includes a plurality of transistors, and a substrate bias voltage supply circuit that is controllable to supply one of a first voltage having the same value as a power supply voltage of the input and output circuit and a second voltage having a value different from the first voltage as a substrate bias voltage to the plurality of transistors, and
said method comprises:
controlling the substrate bias voltage supply circuit to supply the first voltage as the substrate bias voltage to select a lower data transmission rate and operate the semiconductor memory device in a power-savings mode; and
controlling the substrate bias voltage supply circuit to supply the second voltage as the substrate bias voltage to select a higher data transmission rate and operate the semiconductor memory device in a high-performance mode.

15. The method according to claim 14, wherein
the plurality of transistors include a P-channel MOSFET,
the first voltage supplied as the substrate bias voltage of the P-channel MOSFET is a positive voltage, and
the second voltage supplied as the substrate bias voltage of the P-channel MOSFET is a positive voltage greater than the first voltage.

16. The method according to claim 15, wherein
the second voltage has the same value as a power supply voltage of a portion of the semiconductor memory device that is different from the input and output circuit.

17. The method according to claim 14, wherein
the plurality of transistors include an N-channel MOSFET,
the first voltage supplied as the substrate bias voltage of the N-channel MOSFET is a ground voltage, and
the second voltage supplied as the substrate bias voltage of the N-channel MOSFET is a negative voltage.

18. The method according to claim 14, wherein
the plurality of transistors include a P-channel MOSFET and an N-channel MOSFET,
the first voltage supplied as the substrate bias voltage of the P-channel MOSFET is a positive voltage, and
the second voltage supplied as the substrate bias voltage of the P-channel MOSFET is a positive voltage greater than the first voltage.

19. The method according to claim 18, wherein
the P-channel MOSFET and the N-channel MOSFET form a CMOS circuit in which a source of the P-channel MOSFET and a drain of the N-channel MOSFET are connected to each other.

20. The method according to claim 14, wherein the substrate bias voltage supply circuit is controlled to supply the first voltage or the second voltage as the substrate bias voltage in accordance with a set feature command.
